(19) United States
(12) Patent Application Publication
(10) Pub. No.: US 2008/0180647 A1
(43) Pub. Date: Jul. 31, 2008

(54) FOCUS MONITOR MARK, FOCUS MONITORING METHOD, AND DEVICE PRODUCTION METHOD

(75) Inventor: Kanji SUGINO, Tokyo (JP)

Correspondence Address: Young & Thompson, Second Floor, 745 S. 23rd Street, Arlington, VA, 22202, US

(73) Assignee: ELPIDA MEMORY, INC., Tokyo (JP)

(21) Appl. No.: 12/019,728

(22) Filed: Jan. 25, 2008

(30) Foreign Application Priority Data
Jan. 25, 2007 (JP) 2007-015015

(51) Int. Cl. G03F 7/207

(52) U.S. Cl. 355/61

(57) ABSTRACT

The focus monitor mark of the present invention includes two dot groups formed with a plurality of dots comprising a resist that is formed in a protruding manner with respect to a wafer surface, and a measurement region. The mark includes a dot pattern mark in which dot groups are arranged so that the dimensions of each dot increase in accordance with an increase in the distance of the dot from the measurement region, two hole groups comprising a plurality of holes formed in the resist on the wafer surface, and measurement region 3. The mark has a hole pattern mark in which each hole is arranged so that the dimensions of each hole increase in accordance with an increase in a distance of the hole from the measurement region.

This application is based upon and claims the benefit of priority from Japanese patent application No. 2007-015015, filed on Jan. 25, 2007, the disclosure of which is incorporated herein in its entirety by reference.

### BACKGROUND OF THE INVENTION

1. Field of the Invention

The present invention relates to a focus monitor that ascertains a defocus amount as a deviation amount from a best focus position, and more particularly to a focus monitor mark, a focus monitoring method, and a device production method for an exposure apparatus.

2. Description of the Related Art

As patterns used in lithography become even smaller, the focus margins of the patterns are decreasing and it has become necessary to improve the management of focus accuracy of exposure apparatuses. Ascertaining a deviation amount (defocus amount) from the best focus position is referred to as focus monitoring, and several focus monitoring methods have been proposed.

A focus monitoring method that uses an optical distance measuring device will now be described as one example of the related art.

That is, facing line and space patterns are arranged as shown in FIG. 1 as focus monitor marks, and dimensions (distance) A between the line ends are measured to calculate the defocus amount. Since a retreat amount of a resist pattern at a line end increases in accordance with a defocus amount, dimensions A have a characteristic such that they are minimized at the best focus position as shown in FIG. 2. By previously acquiring the focus dependency characteristics of dimensions A (relationship indicating that when dimensions A are a certain nm, the defocus amount is a certain nm), the defocus amount can be calculated based on the measurement result of dimensions A.

However, since dimensions A also fluctuate depending on the exposure dose, when a fluctuation in the actual exposure dose or the like occurs at the exposure apparatus, it is not possible to distinguish and discriminate between exposure dose fluctuations and focus fluctuations. As a method to overcome this problem, a focus monitor mark is disposed as shown in FIG. 3 in which the resist presence/absence state of the above-described focus monitor mark is inverted, and dimensions (distance) B between the edges of the spaces are measured.

Since the retreat amount at the space edges increases in accordance with the defocus amount, dimensions B also exhibit the same focus dependency characteristics as dimensions A with respect to focus fluctuations. In contrast, with respect to exposure dose fluctuations, since dimensions A and dimensions B exhibit opposite behaviour in the respect that dimensions A increase while dimensions B decrease as the exposure dose increases, as shown in FIG. 4, it is possible to distinguish and discriminate between exposure dose fluctuations or focus fluctuations based on the measurement results for both dimensions A and B. Thus, by previously acquiring the exposure dose dependency characteristics of dimensions A and B, it is possible to calculate a pure defocus amount that excludes an exposure dose fluctuation amount.

Further, Japanese Patent Laid-Open No. 2000-171683 discloses a pattern of a mask for measuring a focus position provided with a substantially square inner frame, an outer frame that is provided so as to encompass the inner frame along the outer periphery thereof, and the isolated line of a predetermined width provided between the inner frame and the outer frame. The invention disclosed in Japanese Patent Laid-Open No. 2000-171683 determines an optimum focus position by utilizing the fact that, at a defocus position, for a portion at which an isolated pattern is exposed and transferred, the pattern dimensions become minute and eventually the pattern disappears as the focus becomes more and more defocused.

However, according to a focus monitoring technique of the art related to the above described invention, although a defocus amount can be calculated, it is not possible to determine the defocus direction. This is because the focus dependency characteristics of dimensions A and B form a figure that is substantially symmetrical from left to right taking the best focus position as the center. Likewise, it is not possible to determine a defocus direction according to the method disclosed in Japanese Patent Laid-Open No. 2000-171683.

Thus, according to the method of the art related to this invention, when performing correction for a best focus position of an exposure apparatus it is necessary to again confirm direction at which defocusing is occurring in by using a separate method.

### SUMMARY OF THE INVENTION

Accordingly, in view of the above-described problems, an object of the present invention is to provide a focus monitor mark and a focus monitoring method that, in addition to monitoring a defocus amount and an exposure dose fluctuation amount, make it possible to determine a defocus direction, as well as to provide a device production method.

A focus monitor mark of the present invention for achieving the above-described object includes: a dot pattern mark that includes two dot groups that comprise a plurality of dots comprising a resist that is formed in a protruding manner with respect to a wafer surface, and an inter-dot-group measurement region that is formed between the two dot groups and that measures a distance between the two dot groups, wherein each dot comprising the two dot groups is arranged such that the dimensions of each dot increase in accordance with an increase in a distance of the dot from the inter-dot-group measurement region; and a hole pattern mark that includes two hole groups comprising a plurality of holes that are formed in the resist on the wafer surface, and an inter-hole-group measurement region that is formed between the two hole groups and that measures a distance between the two hole groups, wherein each hole comprising the two hole groups is arranged such that the dimensions of each hole increase in accordance with an increase in the distance of the hole from the inter-hole-group measurement region.

According to the above-described focus monitor mark of the present invention, if a focal point exists between a projection optical system and the resist, the distance between the dot groups becomes greater than the distance between the hole groups, while if the focal point exists on the wafer side the distance between the dot groups becomes less than the distance between the hole groups. This is because when the focal point exists between the projection optical system and the resist, the dots, which have a shape that protrudes from the wafer surface, are liable to disappear, while in contrast, when the focal point exists on the wafer side, the holes are liable to disappear. Hence, according to the focus monitor mark of the present invention that has these properties it is possible to identify a defocus direction based on the size relationship with respect to the distance between the dot groups and the distance between the hole groups.

Further, as the defocus amount increases, the dimensions of the disappearing dot/hole patterns increase and the distance between the dot/hole groups also increases. Hence, by previously measuring the relationship between defocus amounts and distances between dot/hole groups of the focus monitor mark of the present invention, a defocus amount can be calculated based on the distance between the dot/hole groups. Furthermore, although the distance between the dot/hole groups also varies according to fluctuations in the exposure dose, dots and holes have contrary characteristics with respect to such exposure dose fluctuations. Hence, it is also possible to calculate an exposure dose fluctuation amount by previously measuring distances between dot/hole groups with respect to fluctuations in an exposure dose for the focus monitor mark of the present invention.

The focus monitor mark of the present invention may be a mark in which each dot comprising the two dot groups is arranged so that a pitch between each dot widens in accordance with an increase in the distance of the dot from the inter-dot-group measurement region.

Further, the focus monitor mark of the present invention may be a mark in which each hole comprising the two hole groups is arranged so that a pitch between each hole widens in accordance with an increase in the distance of the hole from the inter-hole-group measurement region.

The focus monitor mark of the present invention may also be a mark in which the dot pattern mark and the hole pattern mark are adjacently disposed.

A focus monitoring method according to the present invention includes: preparing a focus monitor mark according to the present invention; measuring a distance between dot groups A′ that is a distance between two dot groups in an inter-dot-group measurement region and also measuring a distance between hole groups B′ that is a distance between two hole groups in an inter-hole-group measurement region; and comparing the measured distance between dot groups A′ and the measured distance between hole groups B′, to determine that a focal point exists between a projection optical system and a resist when A′>B′ and that the focal point exists on a wafer side when B′>A′.

The focus monitoring method according to the present invention may also include calculating a defocus amount based on a measurement result for the distance between dot groups A′ and/or the distance between hole groups B′.

Further, the focus monitoring method according to the present invention may include calculating a fluctuation amount for the distance between dot groups A′ and the distance between hole groups B′ that fluctuate due to fluctuations in an exposure dose.

A device production method according to the present invention includes transferring a mask pattern onto a wafer using a focus monitoring method according to the present invention.

In the focus monitor mark according to the present invention, when a focal point exists between the projection optical system and the resist, the distance between dot groups becomes greater than the distance between hole groups, and when the focal point exists on a wafer side the distance between dot groups becomes less than the distance between hole groups. It is therefore possible to identify a defocus direction based on the size relationship with respect to the distance between dot groups and the distance between hole groups in addition to calculating a defocus amount and an exposure dose fluctuation amount.

### BRIEF DESCRIPTION OF THE DRAWINGS

FIG. 1 is a plan view that illustrates an example of a line-type mark that is used for a focus monitor according to the art related to the present invention;

FIG. 2 is a view illustrating focus dependency characteristics of sectional forms of the resist of a line pattern;

FIG. 3 is a plan view of a mark in which the resist state of the mark shown in FIG. 1 is reversed;

FIG. 4 is a graph showing exposure dose dependency characteristics of inter-pattern dimensions;

FIG. 5 is a plan view of an example of a dot-type mark for a focus monitor according to the present invention;

FIG. 6 is a view showing focus dependency characteristics of sectional forms of the resist of a dot pattern;

FIG. 7 is a graph showing focus dependency characteristics of inter-pattern dimensions;

FIG. 8 is a plan view of an example of a hole-type mark for a focus monitor according to the present invention;

FIG. 9 is a view showing focus dependency characteristics of sectional forms of a resist of a hole pattern;

FIG. 10 is a view showing an example of an exposure apparatus to which the present invention is applied;

FIG. 11A is a plan view of an exemplary embodiment of a focus monitor mark according to the present invention; and

FIG. 11B is a plan view of an exemplary embodiment of a focus monitor mark according to the present invention.

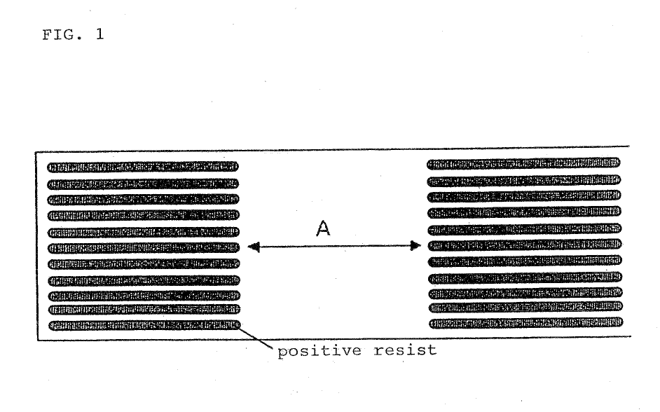

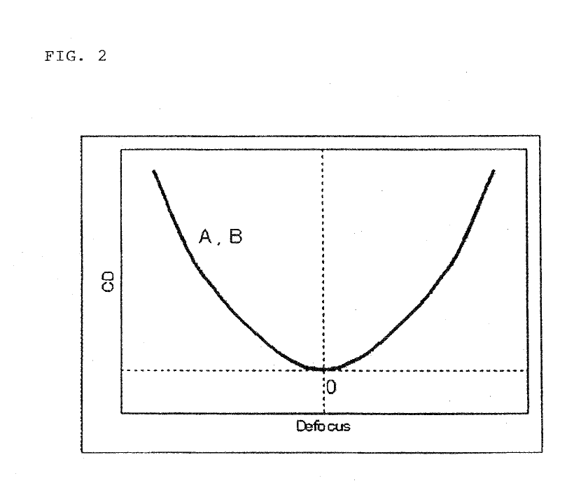

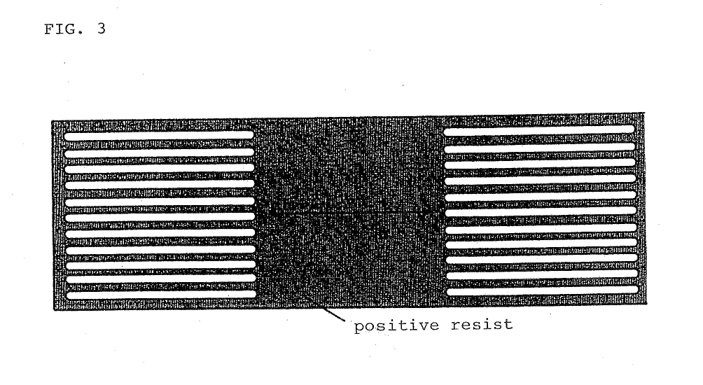

### DETAILED DESCRIPTION OF THE PREFERRED EMBODIMENT(S)

Hereunder, an exemplary embodiment is described while referring to the drawings.

A focus monitor mark according to the present exemplary embodiment is formed using a positive resist on a wafer, and includes dot pattern mark 1 that is a dot-type mark and hole pattern mark 2 that is a hole-type mark. First, dot pattern mark 1 is described.

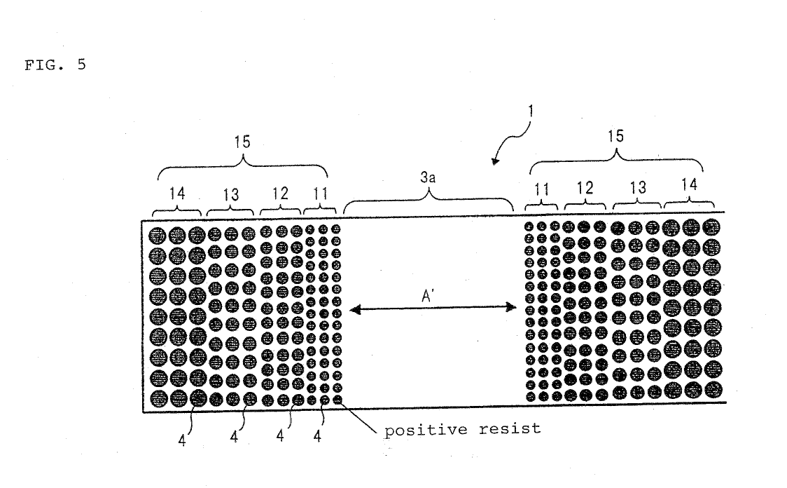

FIG. 5 is a plan view of a dot-type mark for a focus monitor according to the present exemplary embodiment.

Dot pattern mark 1 includes a plurality of dots 4 having differing dimensions that comprise a positive resist that is formed in a protruding manner with respect to the wafer surface. The plurality of dots 4 comprises dot group 15. Two dot groups 15 are disposed on the both sides of measurement region 3a to sandwich measurement region 3a. More specifically, a feature of the focus monitor mark according to the present invention is that a dot pattern, and not a line and space pattern of the art related to the present invention, is arranged in a dense manner.

Each dot group 15 is configured so that the further the position of dot 4 comprising dot group 15 is from the side nearest measurement region 3a, the larger the dimensions of dot 4 are. According to the present exemplary embodiment, as one example thereof, a case is described in which dot group 15 comprises first to fourth dot groups 11 to 14.

The dimensions of first dot group 11 formed in an area adjoining measurement region 3a are the smallest among dot groups 11 to 14. In the example shown in FIG. 5, three columns of dots 4 including 15 dots each are formed to comprise first dot group 11.

The dimensions of second dot group 12 formed in an area adjoining first dot group 11 in a direction away from measurement region 3a are larger than the dimensions of first dot group 11 and smaller than the dimensions of third dot group 13 that is described later. In the example shown in FIG. 5, three columns of dots 4 including 12 dots each are formed to comprise second dot group 12.

The dimensions of third dot group 13 formed in an area adjoining second dot group 12 in a direction away from measurement region 3a are larger than the dimensions of second dot group 12 and smaller than the dimensions of fourth dot group 14 that is described later. In the example shown in FIG. 5, three columns of dots 4 including 10 dots each are formed to comprise third dot group 13.

The dimensions of fourth dot group 14 that is formed in an area that adjoins third dot group 13 and is furthest from measurement region 3a are the largest among first to fourth dot groups 11 to 14. In the example shown in FIG. 5, three columns of dots 4 including 9 dots each are formed to comprise fourth dot group 14.

Regarding the respective pitches of the dots comprising first to fourth dot groups 11 to 14, the pitch of first dot group 11 is the smallest, the pitch increases in the order of second dot group 12 and third dot group 13, and the pitch of fourth dot group 14 is largest.

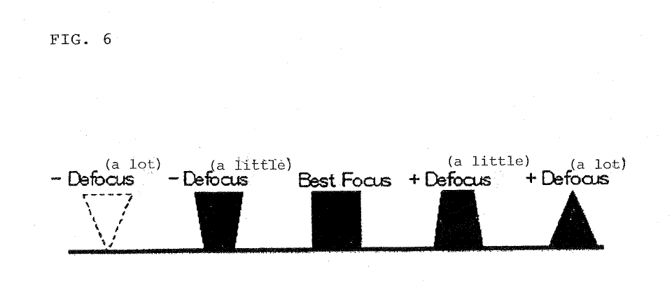

The focus properties of sectional forms of the resist of a dot pattern are illustrated in FIG. 6.

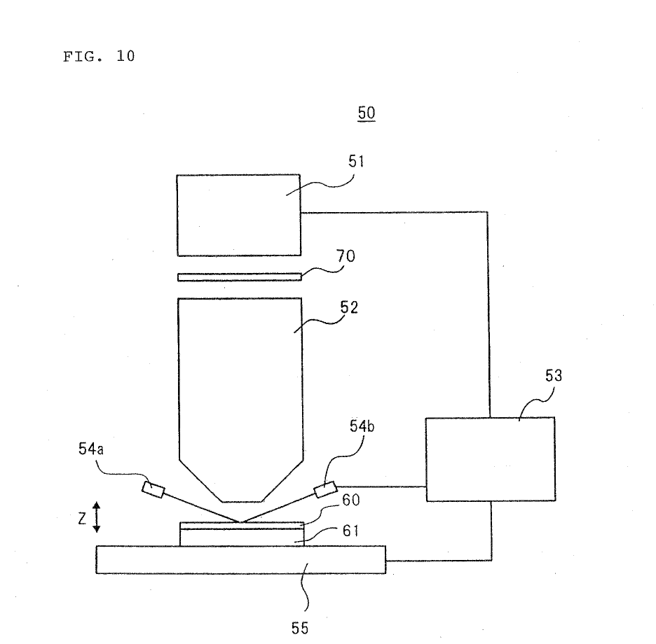

As shown in FIG. 6, it is known that the dot pattern has differing characteristics according to the defocus direction, which are that, with respect to a minus defocus, the resist pattern is liable to disappear since it is formed in a reverse tapered shape while, with respect to a plus defocus, it is hard for the resist pattern to disappear since it is formed in a normal tapered shape. Here, a minus defocus is defined as a case in which a focal point deviates further to the upper side than the resist (between projection optical system 52 and resist 60 in FIG. 10). And a plus defocus is defined as a case in which a focal point deviates further to the lower side than the resist for a plus defocus (wafer 61 direction in FIG. 10). More specifically, by verifying the disappearance of the dot pattern, the focal point can be identified as deviating further to the upper side than the resist. Further, the focus margin of each dot increases as the size of the dot increases.

Dot pattern mark 1 according to the present exemplary embodiment is provided with dots having the same characteristics as dot group 15 that gradually increases in the direction from measurement region 3a to the outer side as described above. That is, since dot group 15 of dot pattern mark 1 is configured so that the dot sizes increase in the direction from the inside to the outside of the focus monitor mark, the focus margin of the dot pattern also increases gradually from the inside to the outside of the focus monitor mark.

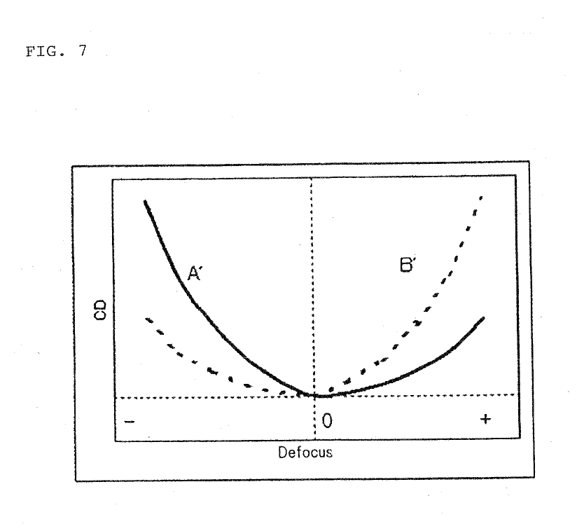

Accordingly, the dot groups sequentially disappear in the direction from first dot group 11 toward fourth dot group 14 for a minus defocus as the defocus amount increases, and in accompaniment therewith, inter-pattern dimensions A′ widen. In this connection, although, as indicated by the solid line in FIG. 7, the focus dependency characteristics of inter-pattern dimensions A′ of dot pattern mark 1 exhibit characteristics such that the best focus position is taken as the vertex and a convex shape is formed thereunder, the defocus amount in a minus direction and the defocus amount in a plus direction have differing characteristics with respect to left-to-right asymmetry.

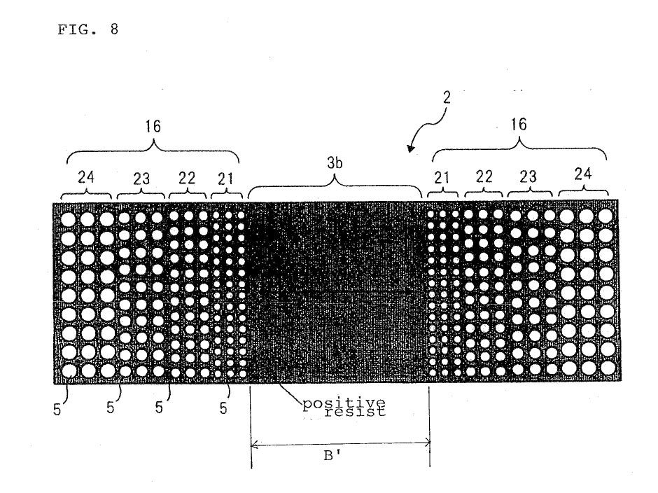

The focus monitor mark of the present exemplary embodiment also includes hole-type marks as shown in FIG. 8 in addition to the dot-type marks having the above described characteristics. The hole-type marks are marks for which the transparent/shaded regions of the pattern on a reticle are reversed with respect to the above-described dot-type mark.

Hole pattern mark 2 includes hole groups 16 on both sides of measurement region 3b in a condition that sandwiches measurement region 3b. Each hole group 16 comprises a plurality of holes 5 having differing dimensions that are formed in a resist on a wafer surface.

Hole group 16 is configured so that the further the position of hole 5 comprising hole group 16 is from the side nearest measurement region 3b, the larger the dimensions of hole 5 are. According to the present exemplary embodiment, as one example thereof, a case is described in which hole group 16 comprises first to fourth hole groups 21 to 24.

The dimensions of first hole group 21 formed in an area adjoining measurement region 3b are the smallest among hole groups 21 to 24. In the example shown in FIG. 8, three columns of holes 5 including 15 holes each are formed to comprise first hole group 21.

The dimensions of second hole group 22 that is formed in an area adjoining first hole group 21 in a direction away from measurement region 3b are larger than the dimensions of first hole group 21 and smaller than the dimensions of third hole group 23 that is described later. In the example shown in FIG. 8, three columns of holes 5 including 12 holes each are formed to comprise second hole group 22.

The dimensions of third hole group 23 that is formed in an area adjoining second hole group 22 in a direction away from measurement region 3b are larger than the dimensions of second hole group 22 and smaller than the dimensions of fourth hole group 24 that is described later. In the example shown in FIG. 8, three columns of holes 5 including 10 holes each are formed to comprise third hole group 23.

The dimensions of fourth hole group 24 that is formed in an area that adjoins third hole group 23 and is furthest from measurement region 3b are the largest among first to fourth hole groups 21 to 24. In the example shown in FIG. 8, three columns of holes 5 including 9 holes each are formed to comprise fourth hole group 24.

Regarding the respective pitches of the holes comprising first to fourth hole groups 21 to 24, the pitch of first hole group 21 is the smallest, the pitch increases in the order of second hole group 22 and third hole group 23, and the pitch of fourth hole group 24 is largest.

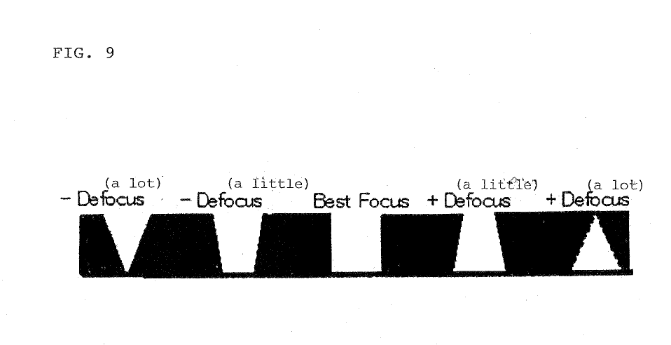

The focus properties of sectional forms of the resist of the hole pattern are illustrated in FIG. 9.

As shown in FIG. 9, the hole pattern has opposite characteristics to the dot pattern in that, with respect to a plus defocus, the resist pattern is liable to disappear since it is formed in a reverse tapered shape, while in contrast, with respect to a minus defocus, it is hard for the resist pattern to disappear since it is formed in a normal tapered shape. More specifically, it is possible to identify that the focal point has deviated further to the lower side than the resist has deviated by verifying the disappearance of the hole pattern. In this connection, similarly to the case of the dot pattern, the focus margin of each hole increases as the size of the hole increases.

Hole pattern mark 2 according to the present exemplary embodiment is provided with holes having the same characteristics as hole group 16 that gradually increases in the direction from measurement region 3b to the outer side as described above. That is, since hole group 16 of hole pattern mark 2 is configured so that the hole dimensions increase in the direction from the inside to the outside of the mark, the focus margin of the hole pattern also increases gradually from the inside to the outside of the mark.

Accordingly, as the defocus amount increases in the case of a plus defocus, hole groups sequentially disappear in the direction from first hole group 21 toward fourth hole group 24, and in accompaniment therewith, inter-pattern dimensions B′ widen. Although, as indicated by the dashed line in FIG. 7, the focus dependency characteristics of inter-pattern dimensions B′ of hole pattern mark 2 exhibit characteristics whereby the best focus position is taken as the vertex and a convex shape is formed thereunder, the defocus amount in a plus direction and the defocus amount in a minus direction have differing characteristics with respect to left-to-right asymmetry.

Since the exposure dose dependencies of the above-described inter-pattern dimensions A′ and B′ exhibit opposite behaviour in that inter-pattern dimensions A′ increase as the exposure dose increases while inter-pattern dimensions B′ decrease as the exposure dose increases, it is possible to distinguish and determine a focus fluctuation or an exposure dose fluctuation based on the measurement results for the two inter-pattern dimensions A′ and B′. By previously acquiring the exposure dose dependency characteristics for inter-pattern dimensions A′ and B′, it is possible to calculate a pure defocus amount that excludes the exposure dose fluctuation amount.

According to the present exemplary embodiment, by previously acquiring the dimension dependency characteristics for exposure dose and for focus of inter-pattern dimensions A′ and B′ and measuring inter-pattern dimensions A′ and B′, it is possible to calculate the defocus amount and exposure dose fluctuation amount. Further, it is also possible to determine the defocus direction based on the size relationship between inter-pattern dimensions A′ and B′. Thus, the present invention makes it possible to implement focus correction of an exposure apparatus simply and with high accuracy. Further, since it is possible to implement a focus monitor with a product wafer by arranging the focus monitor mark of the present invention on a scribe of a product reticle or the like, work to expose a test wafer for focus monitoring is not required, and it is possible to prevent a drop in the utilization rate of the exposure apparatus.

It is to be noted that the above described configuration example of dot pattern mark 1 and hole pattern mark 2 is one example, and the present invention is not limited to the above configuration. More specifically, although a configuration is described above in which, in two dot groups 15 or hole groups 16 of each mark, the sizes of the dots or the sizes of the holes are divided into four levels, the present invention is not limited thereto, and a configuration may be adopted in which a greater number of levels are used. Further, the number of dots or holes and the number of dot columns or hole columns can also be suitably changed as necessary.

Further, although an example is given above in which the shape of dots 4 and holes 5 is circular, the present invention is not limited thereto and, for example, the shape may be polygonal.

### (Exposure Apparatus)

Next, an exposure apparatus to which the present invention is applied is described using FIG. 10.

Exposure apparatus 50 is an apparatus that produces a semiconductor device by exposing and transferring a mask pattern onto a wafer. Exposure apparatus 50 includes illumination system 51 that includes a light source and an illumination optical system, a reticle stage (not shown) that holds mask (reticle) 70 that is illuminated by an illumination light for exposure (hereunder, abbreviated to “illumination light”) from illumination system 51, projection optical system 52 that projects an illumination light that is emitted from mask 70 onto wafer 61, wafer stage 55 that holds wafer 61, light projector 54a and light receiver 54b as a focal point position detection system that can detect a position in the z-direction of wafer 61, and controller 53 that controls these components.

A light from light projector 54a is illuminated on the mark of the present invention, a reflection light thereof is received by light receiver 54b, and that detection result is sent to controller 53. At controller 53, a defocus amount and an exposure dose fluctuation amount are calculated based on measured inter-pattern dimensions A′ and B′, and the defocus direction is also determined based on the size relationship between inter-pattern dimensions A′ and B′. Based on the calculation result, controller 53 drives wafer stage 55 in the z-direction to dispose the surface of wafer 61 at a best focus position that matches the image forming surface of projection optical system 52.

Projection optical system 52 may be any one of a reduction system, an equivalent magnification system, and an enlargement system, and may also be any one of a refractive system, a catadioptric system, and a reflective system.

As the illumination light for exposure it is possible to use not only ultraviolet light such as g-rays, i-rays, KrF excimer laser beam, ArF excimer laser beam, F₂ laser light, and Ar₂ laser beam, but also, for example, EUV light, X-rays, and charged particle rays such as electron beams and ion beams. In addition, as the light source for exposure, it is possible to use not only a mercury lamp or excimer laser, but also a harmonic generating device such as a YAG laser or semiconductor laser, an SOR, a laser plasma light source, or an electron gun or the like.

Exposure apparatuses to which the present invention is applied are not limited to exposure apparatuses used for manufacturing semiconductor devices, and may also be exposure apparatuses that are used in the manufacture of microdevices (i.e., electronic devices) such as liquid crystal display devices, display apparatuses, thin film magnetic heads, image pickup devices (such as CCD), micromachines, and DNA chips and the like, or in the manufacture of photomasks and reticles used in exposure apparatuses.

### EXAMPLE

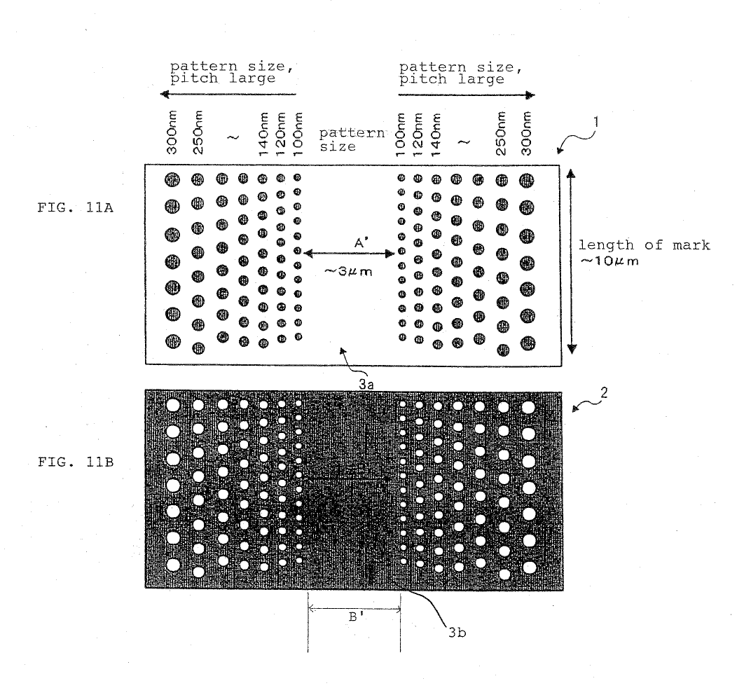

FIG. 11A and FIG. 11B are plan views of one example of the focus monitor mark according to the present invention.

In both dot pattern mark 1 shown in FIG. 11A and hole pattern mark 2 shown in FIG. 11B, inter-pattern dimensions A′ and B′ are approximately 3 μm, and the mark length is approximately 10 μm. There is no particular constraint with respect to the size of the mark.

Regarding the dot patterns and the hole patterns that are disposed, the size of the dots or holes is changed so that the size gradually increases in the outward direction from the side of measurement regions 3a and 3b (inside), and the dots or holes are disposed such that they are bilaterally symmetrical with respect to the mark center. More specifically, when the exposure light source is an ArF/KrF laser, resist dot patterns or resist hole patterns of approximately 100, 120, 140, 160, 180, 200, 250, and 300 nm are sequentially disposed in that order from the inside towards the outside. Regarding the pattern pitch, the pitch is such that the dot (hole):space ratio is from approximately 1:2 to 1:3 so that the resist dot patterns or the resist hole patterns do not join together at a defocus time.

Since the dot-type and hole-type marks are adjacently disposed, inter-pattern dimensions A′ and B′ of both marks are measured together.

Regarding the focus properties of inter-pattern dimensions A′ and B′, since the size of dot/hole patterns that disappear increases in accordance with an increase in the defocus amount, inter-pattern dimensions A′ and B′ also increase. The defocus amount is calculated by utilizing differences in the focus margins for each pattern size such as that, for example, in the case of a defocus amount of 50 nm, although patterns of 100 nm or less disappear, patterns of 120 nm or more remain, while in the case of a defocus amount of 100 nm, although patterns of 140 nm or less disappear, patterns of 160 nm or more remain.

Further, even with respect to the same defocus amounts it is possible to identify the defocus direction by measuring differences in the characteristics of pattern kinds for both marks together, i.e. that a dot pattern is liable to disappear at the time of a minus defocus (dimensions A′>dimensions B′), while a hole pattern is liable to disappear at the time of a plus defocus (dimensions A′<dimensions B′).

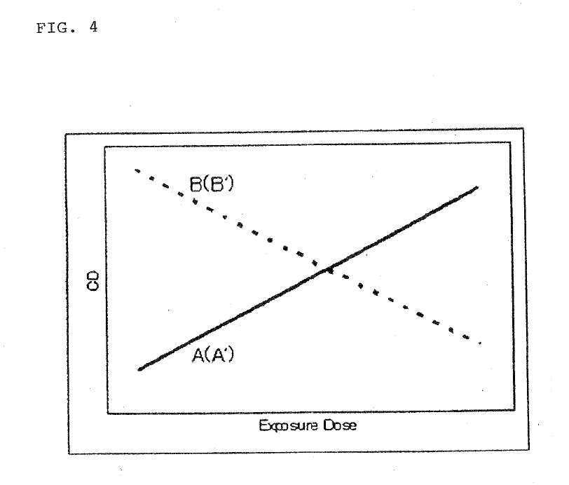

Inter-pattern dimensions A′ and B′ vary according to fluctuations in the exposure dose as shown in FIG. 4. For example, when the exposure dose fluctuates in an increasing direction, on a positive resist, dimensions A′ increase while dimensions B′ decrease. In contrast, on a negative resist, dimensions A′ decrease while dimensions B′ increase. Thus, since dimensions A′ and dimensions B′ always behave in opposite directions, the fluctuation amount of an exposure dose can also be calculated.

According to the focus monitor mark of the present invention, the exposure dose and defocus dependency characteristics of inter-pattern dimensions A′ and B′ are previously acquired, and, based on measurement results for dimensions A′ and B′, it is possible to calculate a defocus amount and an exposure dose fluctuation amount. Furthermore, it is possible to determine the defocus direction based on the size relationship between dimensions A′ and B′.

It is to be noted that since the sensitivity of pattern disappearance will vary depending on the illumination conditions (NA and σ) or the resist film thickness and the like that are used, a certain degree of optimization of pattern size/pitch is necessary for practical purposes.

What is claimed is:

1. A focus monitor mark for optimizing a focus position when exposing and transferring a desired mask pattern onto a wafer using a projection optical system, including:
a dot pattern mark that includes two dot groups that include a plurality of dots comprising a resist that is formed in a protruding manner with respect to a wafer surface, and an inter-dot-group measurement region formed between said two dot groups and that measures a distance between said two dot groups, wherein each dot that comprises said two dot groups is arranged such that dimensions of each of said dots increase in accordance with an increase in a distance of said dot from said inter-dot-group measurement region; and
a hole pattern mark that includes two hole groups that include a plurality of holes formed in said resist on said wafer surface, and an inter-hole-group measurement region that is formed between said two hole groups and that measures a distance between said two hole groups, wherein each of said holes comprising said two hole groups is arranged such that dimensions of each of said holes increase in accordance with an increase in a distance of said hole from said inter-hole-group measurement region.

2. The focus monitor mark according to claim 1, wherein each of said dots comprising said two dot groups is arranged such that a pitch between each of said dots widens in accordance with an increase in a distance of said dot from said inter-dot-group measurement region.

3. The focus monitor mark according to claim 1, wherein each of said holes comprising said two hole groups is arranged such that a pitch between each of said holes widens in accordance with an increase in a distance of said hole from said inter-hole-group measurement region.

4. The focus monitor mark according to claim 1, wherein said dot pattern mark and said hole pattern mark are disposed adjacent to each other.

5. A focus monitoring method for optimizing a focus position when exposing and transferring a desired mask pattern onto a wafer using a projection optical system, including:
preparing a focus monitor mark according to claims 1;
measuring a distance between said dot groups A′ that is a distance between said two dot groups in said inter-dot-group measurement region and also measuring a distance between said hole groups B′ that is a distance between said two hole groups in said inter-hole-group measurement region; and
comparing said distance between said dot groups A′ that is measured and said distance between said hole groups B′ that is measured, and determining that a focal point exists between said projection optical system and said resist when A′>B′, and determining that a focal point exists on said wafer side when A′<B′.

6. The focus monitoring method according to claim 5, further including calculating a defocus amount based on a measurement result for said distance between said dot groups A′ and/or said distance between said hole groups B′.

7. The focus monitoring method according to claim 5, further including calculating a fluctuation amount of said distance between said dot groups A′ and said distance between said hole groups B′ that fluctuate according to fluctuations in an exposure dose.

8. A device production method that uses a focus monitoring method according to claim 5, and includes transferring said mask pattern onto said wafer.
